(19) United States
(12) Patent Application Publication
(10) Pub. No.: US 2013/0065373 A1
(43) Pub. Date: Mar. 14, 2013

(54) Methods and Systems for Forming Implanted Doped Regions for a Semiconductor Device Using Reduced Temperature Ion Implantation

(71) Applicants: Stefan Flachowsky, Dresden (DE); Christian Krueger, Liegau-Augustusbad (DE); Jan Hoentschel, Dresden (DE)

(72) Inventors: Stefan Flachowsky, Dresden (DE); Christian Krueger, Liegau-Augustusbad (DE); Jan Hoentschel, Dresden (DE)

(73) Assignee: GLOBALFOUNDRIES INC., Grand Cayman (KY)

(21) Appl. No.: 13/231,568

(22) Filed: Sep. 13, 2011

(51) Int. Cl. H01L 21/336; H01L 21/265

(52) U.S. Cl. 438/306; 438/527; 257/E21.334; 257/E21.409

(57) ABSTRACT

In one example, a method disclosed herein includes reducing a temperature of at least an implant surface of a semiconducting substrate to a temperature less than −50° C. and after reducing the temperature of the implant surface, performing at least one ion implantation process to implant ions into the substrate with the implant surface at a temperature less than −50° C.

### BACKGROUND OF THE INVENTION

1. Field of the Invention

Generally, the present disclosure relates to the manufacturing of sophisticated semiconductor devices, and, more specifically, to various methods of forming implanted doped regions on a semiconductor device by performing ion implantation processes at a reduced or low temperature, and to various systems for performing such ion implantation processes.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein field effect transistors (NMOS and PMOS transistors) represent one important type of circuit elements that substantially determine performance of the integrated circuits. During the fabrication of complex integrated circuits using, for instance, MOS technology, millions of transistors, e.g., NMOS transistors and/or PMOS transistors are formed on a substrate including a crystalline semiconductor layer. A field effect transistor, irrespective of whether an NMOS transistor or a PMOS transistor is considered, typically comprises so-called PN junctions that are formed by an interface of highly doped regions, referred to as drain and source regions, with a slightly doped or non-doped region, such as a channel region, disposed between the highly doped regions source/drain regions. Device designers are under constant pressure to improve the electrical performance characteristics of semiconductor devices, such as transistors, and the overall performance capabilities of integrated circuit devices that incorporate such devices.

Ion implantation is a technique that is employed in many technical fields to implant dopant ions into a substrate so as to alter the characteristics of the substrate or of a specified portion thereof. For example, the rapid development of advanced devices in the semiconductor industry is based on, among other things, the ability to generate highly complex dopant profiles within tiny regions of a semiconducting substrate by performing advanced implantation techniques through a masking In implanting specified ions into a substrate, the desired lateral implant profile may be readily obtained by providing correspondingly adapted implantation masks. A desired vertical implant profile may be achieved by, among other things, controlling the acceleration energy of the ions during the implantation process such that the majority of the ions at positioned at a desired depth in the substrate. Moreover, by appropriately selecting the dopant dose, i.e., the number of ions per unit area of the ion beam impinging on a substrate, comparably high concentrations of atoms may be incorporated into a substrate as compared to other doping techniques, such as diffusion. In the case of an illustrative transistor, ion implantation may be used to form various doped regions, such as halo implant regions, extension implant regions and deep source-drain implant regions, etc.

An illustrative ion implantation sequence for forming source/drain regions for an illustrative transistor 30 will now be discussed with reference to FIGS. 1A-1C. FIG. 1A depicts the transistor 30 at an early stage of fabrication, wherein a gate electrode structure 14 has been formed above a semiconducting substrate 10 in an active region that is defined by a shallow trench isolation structure 12. The gate electrode structure typically includes a gate insulation layer 14A and a conductive gate electrode 14B. As shown in FIG. 1A, an initial ion implantation process is typically performed to form so-called extension implant regions 16 in the substrate 10. The masking layer that would be used during the implantation sequence shown in FIGS. 1A-1C is not depicted in the drawings. Then, sidewall spacers 18 are formed proximate the gate electrode structure 14. A second ion implantation process is then performed on the transistor 30 to form so-called deep source-drain implant regions 20 in the substrate 10. The ion implantation process performed to form the deep source-drain implant regions 20 is typically performed using a higher dopant dose and it is performed at higher implant energy than the ion implantation process that was performed to form the extension implant regions 16. Thereafter, as shown in FIG. 1C, a heating or anneal process is performed to form the final source drain regions 22 for the transistor 30. This heating process repairs the damage to the lattice structure of the substrate material as a result of the implantation processes and it activates the implanted dopant materials, i.e., the implanted dopant materials are incorporated into the silicon lattice. Of course, the type of dopants implanted, either N-type or P-type dopants, depends upon the type of transistor being made, i.e., an NMOS transistor or a PMOS transistor, respectively. Such implantation processes are performed using well-known, and implantation systems and the implant processes are performed at room temperature, i.e., about 25° C. Using such prior art implantation systems and techniques describe above, the temperature of the substrate 10 may be raised from approximately room temperature to about 80° C. during a typical ion implantation process.

As device dimensions continually being reduced, it is very important that the depth of the source/drain regions for a transistor be very shallow, e.g., approximately 15 nm or less in current-day technologies, and that the implanted dopants are, to the extent possible, fully activated. Thus, heating processes such as a flash anneal or a laser anneal are performed for a very short duration, e.g., 1250° C. for a duration of 2-10 milliseconds, are performed to limit the diffusion of the implanted ions, so as to maintain the desired shallow dopant profile, while at the same time trying to maximize dopant activation. In general, the higher the annealing temperature the greater the extent of dopant activation. For previous device generations, a typical anneal process might be a rapid thermal anneal process performed at a temperature of about 1080° C. for a much longer duration of about 1-2 seconds. However, the very short millisecond anneal times performed to activate very shallow source/drain regions are insufficient to cure all of the damages to the substrate resulting from the ion implantation processes. For example, typical prior art extension implant and deep source/drain implant processes performed on a transistor might be performed with a target implant depth of about 20-30 nm and 50-60 nm, respectively. After a flash or laser anneal process is performed, the source/drain region 22 of the transistor 30 will have an amorphous region (where there is a sufficient concentration of ions to enable the region to conduct current) and a semi-amorphous regions (where implanted ions are not of sufficient concentration or not activated). The depth of the amorphous regions may be approximately 3-7 nm and 40-50 nm, for the extension implant region and the deep source/drain implant region, respectively, of the source/drain region 22 of the transistor 30. As a result, the depth of the semi-amorphous region would tend to overlap with the pn-junction in the source/drain region of the device, which may result in higher leakage currents which tend to reduce the electrical performance of the resulting device and an integrated circuit device incorporating such transistors.

The present disclosure is directed to various ion implantation methods and systems for forming doped regions in a semiconducting substrate that may solve or reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming implanted doped regions on a semiconductor device by performing ion implantation processes at a reduced or low temperature, and to various systems for performing such ion implantation processes. In one example, a method disclosed herein includes reducing a temperature of at least an implant surface of a semiconducting substrate to a temperature less than −50° C. and after reducing the temperature of the implant surface, performing at least one ion implantation process to implant ions into the substrate with the implant surface at a temperature less than −50° C.

In another illustrative example, a method disclosed herein includes positioning a semiconducting substrate on a wafer chuck of an ion implant tool, cooling the wafer chuck to a temperature of less than −50° C. and after cooling the wafer chuck, performing at least one ion implantation process to implant ions into the substrate.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1C depicts one illustrative prior art process flow for forming doped regions in a semiconductor device;

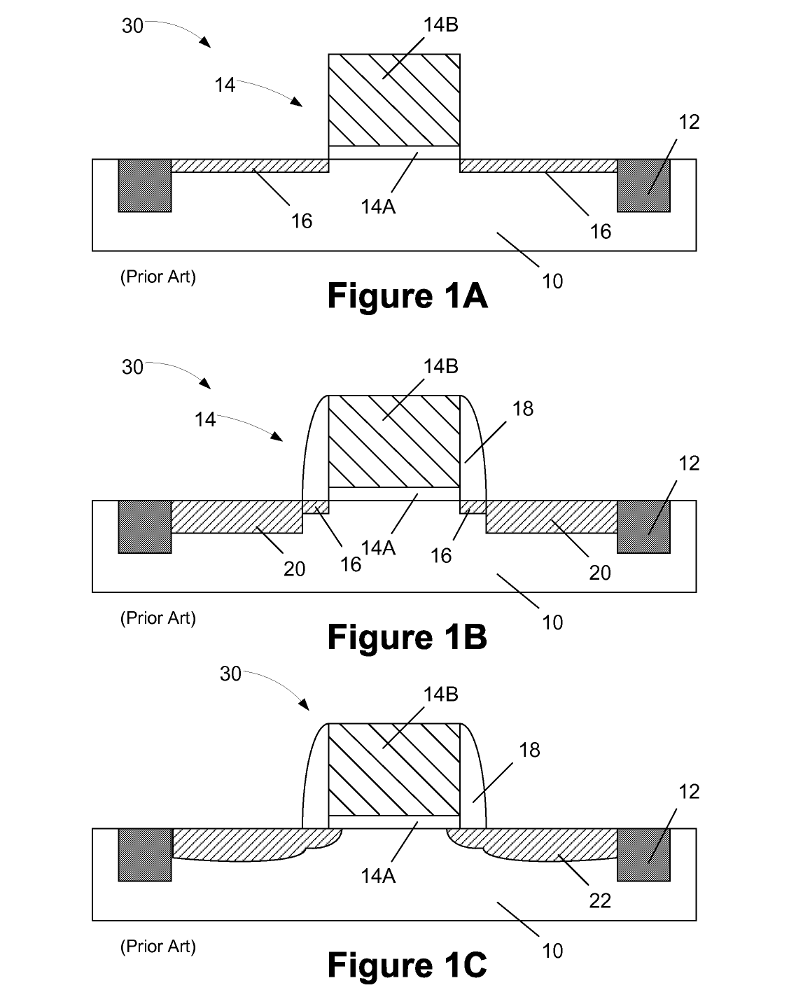

FIG. 2 depicts one illustrative example of a novel ion implantation system described herein; and

FIGS. 3A-3C depict various illustrative methods and systems for forming implanted doped regions by performing reduced temperature ion implantation processes.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

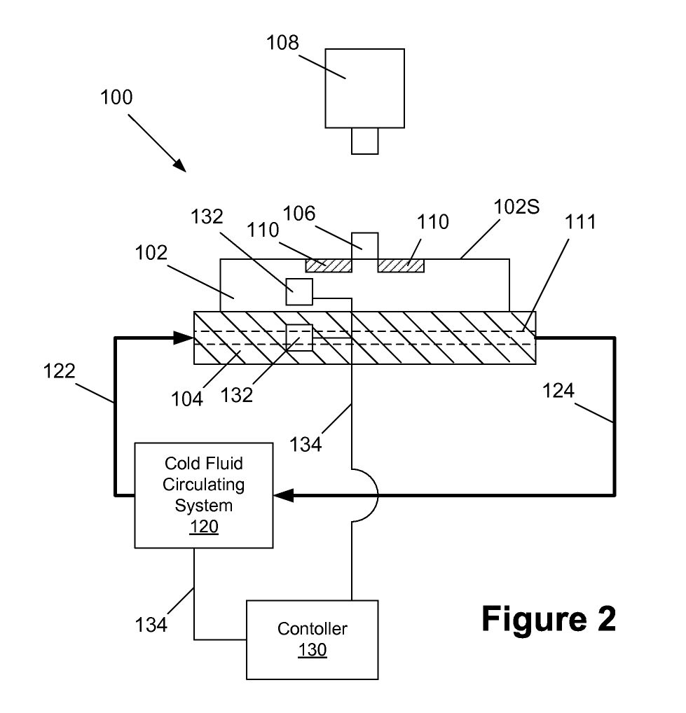

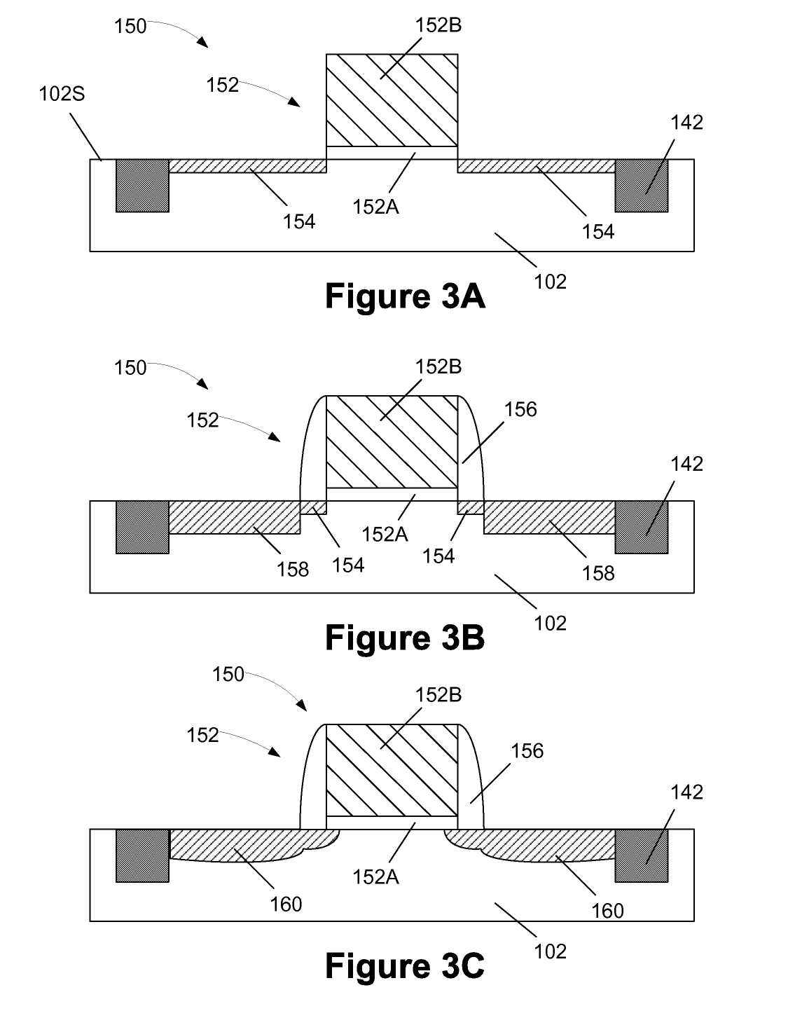

The present disclosure is directed to various methods and systems for forming implanted doped regions on a semiconductor device, such as a transistor, by performing reduced temperature ion implantation processes. As will be readily apparent to those skilled in the art upon a complete reading of the present application, the present methods and systems are applicable to a variety of technologies, e.g., NMOS, PMOS, CMOS, etc., and they are readily applicable to a variety of devices, including, but not limited to, logic devices, memory devices, etc. With reference to FIGS. 2 and 3A-3C, various illustrative embodiments of the methods and systems disclosed herein will now be described in more detail.

The inventors have discovered that by performing ion implantation processes at reduced temperatures, as compared to performing them at room temperature, as is the current practice, results in a semiconductor device with increased electrical performance characteristics, such as reduce leakage currents. Such reduced temperature implantation techniques also permits the continued use of very short duration anneal processes, such as flash or laser anneal processes, to thereby reduce the migration of the implanted dopant materials.

FIG. 2 is a simplified, schematic drawing of one illustrative ion implantation system 100 disclosed herein for forming illustrative doped regions 110 in an illustrative semiconducting substrate 102 at temperatures below room temperature, i.e., below 25° C. As shown therein, in one illustrative embodiment, the ion implantation system 100 includes a schematically depicted wafer chuck 104, a schematically depicted ion implanter 108, for directing energized ions toward the substrate 102, a cold fluid circulating system 120, and a controller 130. The wafer chuck 104 is adapted to hold the illustrative substrate 102 when an ion implantation process is performed on the substrate 102. A portion of a semiconductor device 106, such as an illustrative gate electrode structure, is schematically depicted above the substrate 102. The controller 130 may be any type of type of device, such as computer, a microprocessor, a microcontroller, etc., that is capable of controlling the functions of the system 100, as described herein.

In one illustrative embodiment, the cold fluid circulating system 120 contains the necessary equipment and facilities for circulating a cold fluid, i.e., a liquid or a gas, through one or more schematically depicted flow paths 111 formed in the wafer chuck 102. The cold fluid circulating system 120 may be either a closed or open system. In one embodiment, cold fluid flows to the chuck 104 via schematically depicted flow line 122 and relatively warmer fluid is returned to the cold fluid circulating system 120 via the schematically depicted flow line 124. In some cases, the returning fluid may simply be discarded and not reused. The cold fluid circulating system 120 may include one or more fluid moving devices (not shown) such as a pump, or a compressor/fan assembly, depending upon the nature of the circulating fluid. A reservoir (not shown) may be provided with the cold fluid circulating system 120 to store the circulating fluid or the circulating fluid may be stored in another piece of equipment. Alternatively, the circulating fluid may simply be provided to the cold fluid circulating system 120 via another source (not shown). The number, size configuration and placement of the lines 122, 124 and the flow paths 111 may vary depending upon the particular application and factors such as the nature of the circulating fluid, the desired temperature of the chuck 104 and the implant surface 102S of the substrate 102.

As an alternative, the system 100 may be configured such that it an ion implantation tool that contains what is in effect a refrigerated process chamber or region where the substrate 102 is positioned before and/or during the implantation process. In this embodiment, the circulating fluid would be a cold gas. The controller 130 would be adapted to control the ambient temperature within the process chamber so as regulate the temperature of implant surface 102S of the substrate 102 and/or the temperature of the chuck 104 prior to and/or during the ion implantation process. The controller 130 may receive or obtain data from various temperature sensors that are adapted to sense at least the temperature of the substrate 102, the temperature of the chuck 104 and/or the ambient temperature in the process chamber. Based upon this information, the controller 130 could then take whatever actions are necessary to maintain the ambient temperature in the process chamber, the temperature of the implant surface 102S, the temperature of the chuck 104 and/or the temperature of the substrate 102 at a desired level or within a desired temperature range. Alternatively, prior to performing the implantation process, the substrate 102 may be positioned or maintained at a location remote from the ion implant tool, e.g., a remote refrigeration unit, where the substrate 102 is cooled to a desired temperature or temperature range prior to performing the implant process. In this embodiment, the system may not separately monitor the temperature of the substrate 102, or the implant surface 102S of the substrate, as the ion implantation process is being performed. Rather, the substrate 102 would be cooled enough prior to beginning the implantation process such that the implant surface 102 will remain below a desired temperature throughout the implantation process.

As noted earlier, the controller 130 is any type of type of device, such as computer, a microprocessor, a microcontroller, etc., that is capable of controlling at least the cooling capabilities of the system 100, as described herein. In some applications, the controller 130 may control all of the functions of the system 100. The illustrative controller 130 may be part of the control system of the basic ion implant tool; it may be included as part of the cold fluid circulating system 120 or it may be a stand-alone device with a single dedicated function. The controller 130 monitors various aspects of the system 100 and controls various operations via one or more feedback loops. For example, via various sensors and gauges (not shown), the controller 130 may monitor the flow rate and temperature of the circulating fluid at various points in the system 120 and the pressure within the lines 122, 124 and/or flow paths 111 system. The controller 130 may also receive inputs from schematically depicted temperature sensors 132 that are adapted to sense the temperature of the chuck 104, the temperature of the implant surface 102S and/or the bulk temperature of the substrate 102. It should be understood that the sensors 132 are intended to be merely representative of any type and any number of temperature sensing devices that may be placed at various locations within the system 100. Moreover, the depiction of the sensors 132 in FIG. 2 is not intended to imply that the temperature sensors 132 must be contact sensors. In some cases, the temperature sensors 132 may simply sense the temperature of the atmosphere proximate the implant surface 102S of the substrate 102 or the atmosphere within a process chamber in which the substrate 102 is positioned. Of course, based upon empirical testing data or perhaps calculations, the sensed bulk temperature of the substrate 102, the sensed temperature of the chuck 104 and/or the sensed temperature of the processing ambient may be correlated with the temperature of the implant surface 102S of the substrate 102. That is, the temperature of the implant surface 102S may be directly sensed or it may be inferred from sensing the temperature of other structures.

Of course, there are many aspects of a real-world ion implant tool that are not depicted in the drawings so as not to obscure the present invention. For example, such a real-world ion implant system 100 would likely include, among other things, an ion source with an input that is connected to respective precursor source gases, such as boron fluoride (BF₃), phosphorous hydride (PH₃), arsenic hydride (AsH₃), carbon fluoride (CF₄) and the like, from which an appropriate ion species may be created in the ion source. The ion source is typically configured to establish a plasma atmosphere and to pre-accelerate charged particles into a beam pipe. Also not depicted is an accelerator tube that is typically positioned downstream of the ion source, that is adapted to accelerate ions with a specified voltage, which may typically range from zero to approximately 200 keV for a typical medium current-day implanter and may range to several hundred keVs or even to 1 MeV or more in high-energy implanters. Typically located downstream of the accelerator tube is a beam shaping element, such as a quadruple magnet, followed by a deflector magnet. A further beam shaping element, such as a quadruple magnet, may be provided downstream of the deflector magnet.

The illustrative system 100 depicted herein is adapted to form any type of a doped region in a semiconducting substrate using any type of dopant material, e.g., any species of and N-type dopant or a P-type dopant. With reference to FIGS. 3A-3C, for purposes of further disclosure, use of the system 100 in forming illustrative extension implants and illustrative source/drain implants for an illustrative transistor 150 will now be described, but the present invention should not be considered as limited to such an example, unless such limitations are expressly set forth in the attached claims. The masking layer that would be used during the implantation sequence shown in FIGS. 3A-3C is not depicted in the drawings so as not to obscure the present inventions.

In the illustrative example depicted in FIG. 3A-3C, the circulating fluid was liquid nitrogen and it was circulated through the chuck 104 during the implantation sequence described below. Depending upon a variety of factors, other possible circulating fluids include, for example, helium, etc. The temperature of the circulating fluid was approximately −105° C. as it entered the wafer chuck 104 and approximately −95° C. as it exited the wafer chuck 104. In one illustrative embodiment, during the implantation processes described below, the temperature of the chuck 104 was monitored using one of the illustrative temperature sensors 132. The circulating fluid was circulated throughout the entirety of each of the implantation processes described below. Prior to beginning the initial implantation process, the room-temperature substrate 102 was pre-cooled to a temperature of about −100° C. in a refrigeration unit and thereafter placed on the wafer chuck 104 and cold circulating fluid was forced through the chuck 104 to keep the substrate 102 at a reduced temperature. Using the illustrative system disclosed herein, the temperature of the implant surface 102S of the substrate may be determined or inferred using at least one of three techniques. In one technique, the temperature of the implant surface 102S may be determined based upon a correlation between the temperature of the implant surface 102S and the sensed temperature of the wafer chuck 104 obtained from a contact thermocouple operatively coupled to the chuck 104. In another technique, the temperature of the implant surface 102S may be correlated to the heat lost by the circulating fluid that circulates through the chuck 104 or by measuring the temperature of the returning fluid and correlating that to the temperature of the implant surface 102S. Yet another technique that might be employed would involve directly measuring the temperature of the temperature of the implant surface 102S of the substrate. Other techniques for determining, measuring or inferring the temperature of the implant surface 102S of the substrate 102 may also be employed using the novel methods disclosed herein.

When the temperature of the wafer chuck 104 reached a temperature of about −100° C., the initial ion implantation process described below to form the so-called extension implant regions in the substrate 102 was initiated. Throughout the ion implantation process sequence describe below, the temperature of the wafer chuck 104 and the flow rate of cold circulating fluid was regulated such that the temperature of the wafer chuck 104 was maintained at −100° C.±5° C. In general, the inventors have discovered that the temperature of the implant surface 102S should be cooled to at least a minimum temperature of about −50° C. during the implantation processes.

FIG. 3A depicts the transistor 150 at an early stage of fabrication, wherein a gate electrode structure 152 has been formed above a semiconducting substrate 102 in an active region that is defined by a shallow trench isolation structure 142. The gate electrode structure typically includes a gate insulation layer 152A and a conductive gate electrode 152B. The substrate 102 may have a variety of configurations, such as the depicted bulk silicon configuration. The substrate 102 may also have a silicon-on-insulator (SOI) configuration that includes a bulk silicon layer, a buried insulation layer and an active layer, wherein semiconductor devices are formed in and above the active layer. Thus, the terms substrate or semiconductor substrate should be understood to cover all forms of semiconductor structures. The substrate 102 may also be made of materials other than silicon. As will be recognized by those skilled in the art after a complete reading of the present application, the gate electrode structures 152 may be of any desired construction and comprised of any of a variety of different materials, such as one or more conductive layers made of polysilicon or a metal, etc., and one or more layers of insulating material, such as silicon dioxide, a high-k material, etc. Additionally, the gate electrode structure 152 for an NMOS transistor may have different material combinations as compared to a gate electrode structure 152 for a PMOS transistor. Thus, the particular details of construction of gate electrode structure 152, and the manner in which the gate electrode structure 152 is formed, should not be considered a limitation of the present invention. For example, the gate electrode structure 152 14 may be made using so-called “gate-first” or “gate-last” techniques.

As shown in FIG. 3A, in this illustrative example, the system 100 was used to perform an initial ion implantation process to form so-called extension implant regions 154 in the substrate 102. In this illustrative example, the extension ion implantation process was performed using arsenic at a dopant dose of 1-2 e¹⁵ ions/cm² and at an energy level of about 2-5 keV. In this illustrative example, the extension implant regions 154 had a target depth of about 20-30 nm.

Next, as shown in FIG. 3B, sidewall spacers 156 are formed proximate the gate electrode structure 152. A second ion implantation process is then performed on the transistor 150 to form so-called deep source-drain implant regions 158 in the substrate 102. In this illustrative example, the deep source-drain ion implantation process was performed using arsenic at a dopant dose of 3-4 e¹⁵ ions/cm² and at an energy level of about 10-25 keV. In this illustrative example, the deep source-drain implant regions 158 had a target depth of about 50-60 nm.

Thereafter, as shown in FIG. 3C, a heating or anneal process is performed at a temperature of about 1150° C. for a duration of about 2-10 milliseconds using a regular spike RTA process to form the final source drain regions 160 for the transistor 150. This heating process repairs the damage to the lattice structure of the substrate 102 as a result of the implantation processes and it activates the implanted dopant materials. Of course, the type of dopants implanted, either N-type or P-type dopants, depends upon the type of transistor 150 being made, i.e., an NMOS transistor or a PMOS transistor, respectively.

A typical prior art implantation sequence comprised of an extension implant process and a deep source/drain implant process was performed on a substrate at room temperature using the same parameters as noted above, e.g., with a target implant depth of about 20-30 nm for the extension implant and 50-60 nm for the deep source drain implant, respectively. After an anneal process was performed, the depth of the amorphous region using the prior art, room temperature implant technique was approximately 3-7 nm and 40-50 nm, for the extension implant region and the deep source drain implant region, respectively. In contrast, using the reduced temperature ion implant techniques described herein, the depth of the amorphous region was approximately 20 nm and approximately 70 nm, for the extension implant region and the deep source drain implant region, respectively. That is, by use of the novel processes described herein, the depth of the interface between the amorphous region and the semi-amorphous region in the substrate 102 is effectively pushed deeper into the substrate 102 as compared to the shallower location of that interface using room temperature ion implantation processes. As a result of the increased depth of the amorphous region achieved by using the methods disclosed herein, the amorphous region may extend beyond the pn-junction in the source/drain region of the device, which may result in very low or at least reduced leakage currents (as compared to the prior art) which tend to increase the electrical performance of the resulting device and an integrated circuit device incorporating such transistors.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
reducing a temperature of at least an implant surface of a semiconducting substrate to a temperature less than −50° C.;
after reducing said temperature of said implant surface, performing at least one ion implantation process to implant ions into said substrate with said implant surface at a temperature less than −50° C.; and
performing an anneal process on said substrate for a duration of about 2-10 milliseconds at a temperature of at least 1150° C.

2. The method of claim 1, further comprising maintaining said implant surface of said semiconducting substrate at a temperature less than −50° C. throughout said at least one ion implantation process.

3. The method of claim 1, wherein performing said at least one ion implantation process comprises performing a first extension implant process and a second deep source/drain implant process for a transistor that is to be formed in and above said semiconducting substrate.

4. (canceled)

5. The method of claim 1, wherein said implanted ions are comprised of an N-type dopant material or a P-type dopant material.

6. The method of claim 1, wherein reducing said temperature of at least said implant surface of said semiconducting substrate comprises circulating a cooling fluid through a chuck on which said substrate is positioned during said at least one ion implantation.

7. The method of claim 6, further comprising monitoring a temperature of at least one of said cooling fluid, said implant surface, said semiconducting substrate or said chuck during said at least one ion implantation.

8. The method of claim 1, wherein reducing said temperature of at least said implant surface of said semiconducting substrate comprises reducing a temperature of a process ambient during said at least ion implantation process.

9. The method of claim 1, wherein reducing said temperature of at least said implant surface of said semiconducting substrate comprises reducing said temperature of said implant surface prior to positioning said substrate in a process tool where said at least one ion implantation process will be performed.

10. A method, comprising:
positioning a semiconducting substrate on a wafer chuck of an ion implant tool;
cooling said wafer chuck to a temperature of less than −50° C. by circulating a cooling fluid through said wafer chuck; and
after cooling said wafer chuck, performing at least one ion implantation process to implant ions into said substrate.

11. (canceled)

12. The method of claim 10, wherein said cooling fluid is circulated throughout the entirety of said at least one ion implantation process.

13. The method of claim 10, further comprising monitoring a temperature of said cooling fluid during said at least one ion implantation process.

14. The method of claim 10, further comprising monitoring a temperature of said wafer chuck during said at least one ion implantation process.

15. The method of claim 10, further comprising maintaining said wafer chuck at a temperature of less than −50° C. during said at least one ion implantation process.

16. The method of claim 10, further comprising, after performing said at least one ion implantation process, performing an anneal process on said semiconducting substrate for a duration of about 2-10 milliseconds at a temperature of at least 1150° C.
